(19) United States
(12) Patent Application Publication
(10) Pub. No.: US 2008/0102542 A1
(43) Pub. Date: May 1, 2008

(54) Wafer processing method

(75) Inventor: Katsuharu Negishi, Ota-ku (JP)

Correspondence Address: GREER, BURNS & CRAIN, 300 S WACKER DR, 25TH FLOOR, CHICAGO, IL, 60606, US

(73) Assignee: Disco Corporation, Tokyo (JP)

(21) Appl. No.: 11/980,847

(22) Filed: Oct. 31, 2007

(30) Foreign Application Priority Data
Oct. 31, 2006 (JP) 2006-295293

(51) Int. Cl. H01L 21/66

(52) U.S. Cl. 438/16; 257/E21.53

(57) ABSTRACT

An inspection step for inspecting the cut state of a wafer that has been cut such as the state of the width of a cut groove, the state of a chip and the like is performed during cutting of a wafer held by another chuck table by making use of the fact that the chuck tables are two in number, that is, compose of first and second chuck tables. Thus, the cut state of the wafer can be inspected without sacrificing throughput, thereby improving the productivity of wafers to be cut.

### BACKGROUND OF THE INVENTION

1. Field of the Invention

The present invention relates to a wafer processing method.

2. Description of the Related Art

A wafer formed with a plurality of devices such as ICs or LSIs which are sectioned by predetermined dividing lines is divided by a cutting machine such as a dicing apparatus into individual devices, which are used in electronic equipment such as cellular phones, personal computers and the like. The cutting machine includes a chuck table for holding a wafer; cutting means attached with a cutting blade for cutting the wafer held by the chuck table; processing-transfer means for processing-transferring the chuck table in an X-axial direction; and indexing-transfer means for indexing-transferring the cutting means in a Y-axial direction perpendicular to the X-axial direction. The cutting machine further includes a cassette table on which a cassette storing a plurality of wafers therein is placed; taking-out means for taking out a wafer from the cassette; a temporarily placing table adapted to temporarily place the wafer taken out thereon; conveying means for conveying the wafer temporarily placed on the temporarily placing table to the chuck table; and alignment means for imaging the wafer held by the chuck table and detecting an area to be cut. The cutting machine thus configured can efficiently divide the wafer into individual devices.

The cutting machine configured as above positions the wafer held by the chuck table at a position immediately below the alignment means and inspects it in order to check its cut state such as the state of a width of a cut groove, the state of a chip and the like after the wafer has been cut. Consequently, a new wafer cannot be held on the chuck table until the inspection of the cut wafer is finished, which poses a problem of lowering throughput and thus of poor productivity.

Japanese Patent Laid-open No. Sho 62-53804 or Japanese Patent No. 3765265 proposes a cutting machine having two chuck tables, in which cutting operation is performed on a wafer on one of the chuck tables while alignment operation is concurrently performed on a to-be-cut wafer held on the other chuck table. However, they do not refer to how to inspect the wafer that has been cut, thus not solving the problem described above.

### SUMMARY OF THE INVENTION

It is, therefore, an object of the invention to provide a wafer processing method that does not deteriorate productivity even if a check is performed on the cut state of a wafer that has been cut.

In accordance with an aspect of the present invention, there is provided a wafer processing method using a cutting machine that includes: a chuck table for holding a wafer; cutting means attached with a cutting blade for cutting the wafer held by the chuck table; processing-transfer means for processing-transferring the chuck table in an X-axial direction; indexing-transfer means for indexing-transferring the cutting means in a Y-axial direction perpendicular to the X-axial direction; a cassette table mounted with thereon a cassette storing a plurality of wafers mounted thereon; taking-out means for taking out a wafer from the cassette; a temporarily placing table adapted to temporarily place the wafer thus taken out; conveying means for conveying to the chuck table the wafer thus temporarily placed on the temporarily placing table; alignment means for imaging the wafer held by the chuck table and detecting an area to be cut; wherein the chuck table includes first and second chuck tables juxtaposed to each other and the processing-transfer means includes first processing-transfer means for processing-transferring the first chuck table and second processing-transferring means for processing-transferring the second chuck table, the method comprising: a wafer holding step in which each of the first and second chuck tables holds a wafer that is taken out from the cassette to the temporarily placing table and then conveyed by the conveying means; an alignment step in which the wafer held by each of the first and second chuck tables is positioned immediately below the alignment means, which detects an area to be cut; a first cutting step in which the cutting blade of the cutting means is positioned for the wafer that has been held by the first chuck table and has been subjected to the alignment step; a second cutting step in which after the first cutting step has been finished, the cutting blade of the cutting means is positioned for and cuts the wafer that has been held by the second chuck table, subjected to the alignment step and is not yet cut; an inspection step in which after the first cutting step has been finished, during the second cutting step, the wafer that has been cut in the first cutting step and held by the first chuck table is positioned immediately below the alignment means, which inspects a cut state.

Preferably, the subsequent wafer holding step and alignment step for the first chuck table in which the inspection step has been finished are performed during the second cutting step.

According to the wafer processing method of the present invention, the inspection step for inspecting the cut state of the wafer that has been cut such as the state of the width of a cut groove, the state of a chip and the like is performed during cutting of a wafer held by another chuck table by making use of the fact that the chuck tables are two in number. Thus, the cut state of the wafer can be inspected without sacrificing throughput, thereby improving the productivity of wafers to be cut.

According to the wafer cutting method of the present embodiment, not only the inspection step but also the subsequent wafer holding step and alignment step after the completion of the inspection step are performed during cutting of the wafer held by another chuck table. Thus, it is possible to improve the productivity of the wafers by optimizing the fact that the chuck tables are two in number.

The above and other object, features and advantages of the present invention and the manner of realizing them will become more apparent, and the invention itself will best be understood from a study of the following description and appended claims with reference to the attached drawings showing some preferred embodiments of the invention.

### BRIEF DESCRIPTION OF THE DRAWINGS

FIG. 1 is a partially cutaway perspective view of a cutting machine used to perform a wafer processing method according to an embodiment of the present invention;

FIG. 2 is a perspective view illustrating an essential portion of the cutting machine shown in FIG. 1;

FIG. 3 is a perspective view illustrating a configuration around cutting means by way example;

FIG. 4 is a lateral view illustrating the configuration around the cutting means by way of example;

FIG. 5 is a time-series explanatory diagram illustrating steps performed correspondingly to first and second chuck tables; and

FIG. 6 is an explanatory diagram schematically illustrating a state where an inspection step is performed during a cutting step.

### DETAILED DESCRIPTION OF THE PREFERRED EMBODIMENTS

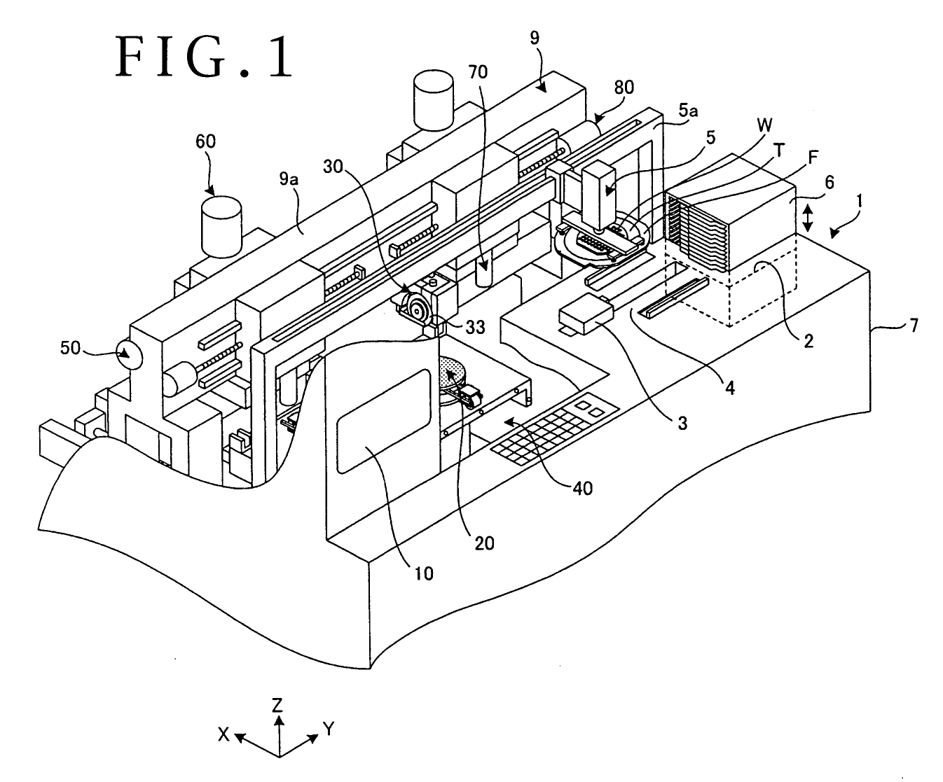

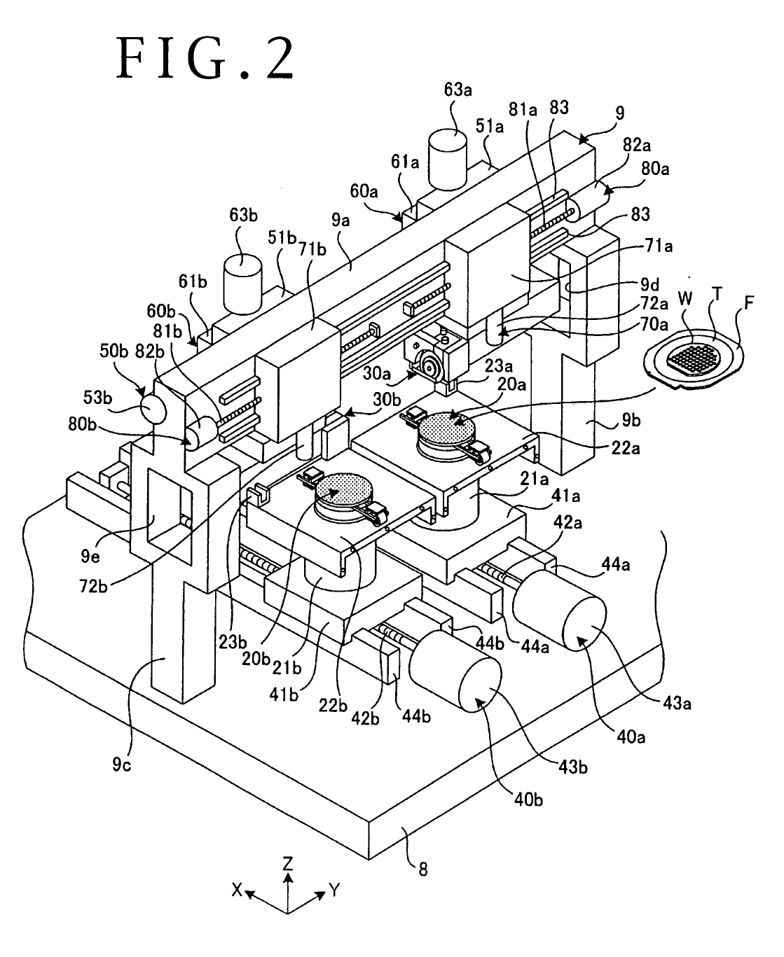

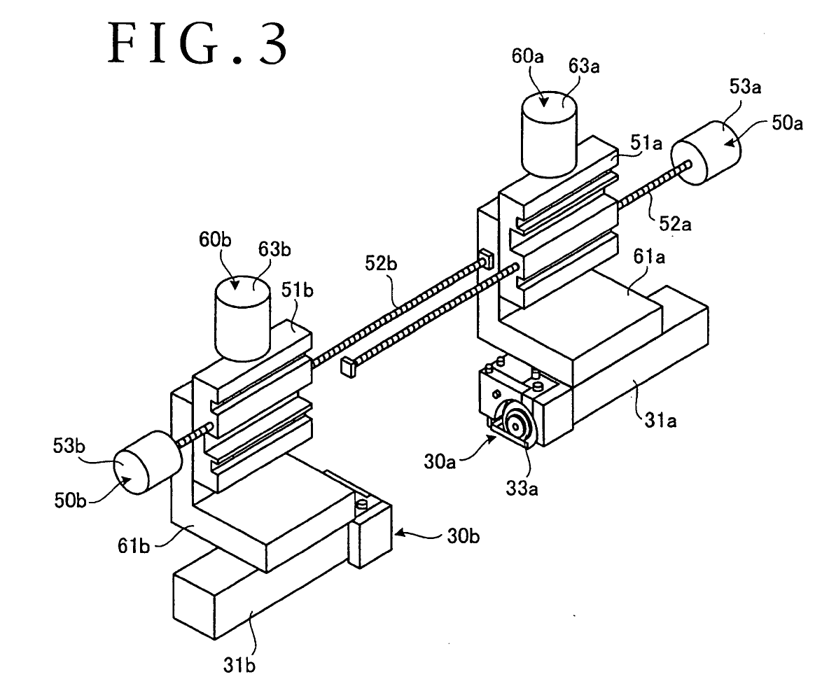

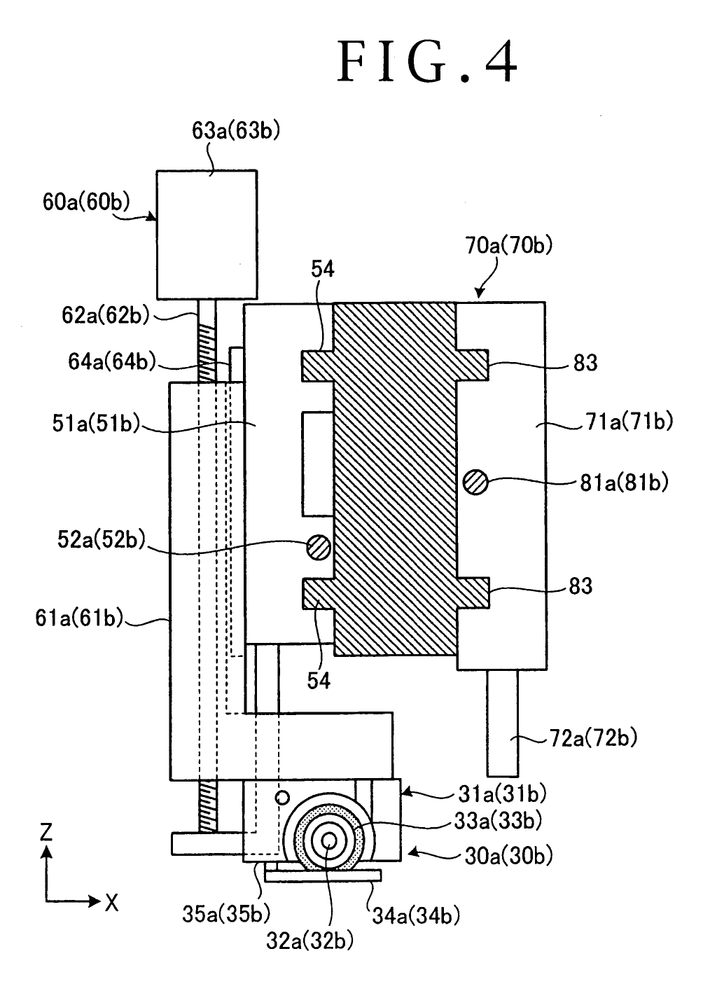

A description will hereinafter be made of a wafer processing method according to an embodiment of the present invention with reference to the drawings. FIG. 1 is a partially cutaway perspective view of a cutting machine used to perform a wafer processing method according to an embodiment of the present invention with a portion thereof cut away. FIG. 2 is a perspective view illustrating an essential portion of the cutting machine shown in FIG. 1. FIG. 3 is a perspective view illustrating a configuration around cutting means by way of example. FIG. 4 is a lateral view illustrating the configuration around the cutting means by way of example.

A cutting machine 1 of the present embodiment is adapted to cut a wafer W along predetermined dividing lines. Referring to FIG. 1, the cutting machine 1 schematically includes a cassette table 2, taking-out means 3, a temporarily placing table 4, conveying means 5, a monitor 10, a chuck table 20, cutting means 30, processing-transfer means 40, indexing-transfer means 50, incision-transfer means 60, alignment means 70 and alignment indexing-transfer means 80.

The cassette table 2 on which a cassette 6 is placed is disposed at one end of an apparatus casing body 7 so as to be movable upward and downward in a Z-axial direction. The cassette 6 stores a plurality of wafers W each of which is integral with an annular frame F via a holding tape T. The wafer W is formed on its front surface with a plurality of rectangular areas sectioned by a plurality of predetermined dividing lines (streets) formed in a lattice-like manner. Devices are formed in the plurality of respective rectangular areas. The taking-out means 3 takes out a wafer W stored in the cassette 6 and places it on the temporarily placing table 4 from which the conveying means 5 can convey the wafer W. The temporarily placing table 4 is adapted to place thereon the wafer W taken out by the taking-out means 3. The conveying means 5 conveys onto the chuck table 20 the wafer W taken out on the temporarily placing table 4 while gripping the frame F of the wafer W.

In the present embodiment, the chuck table 20 composes of two chuck tables juxtaposed to each other in the Y-axial direction as described later. A conveying rail 5a of the conveying means 5 is formed as a gate type column support structure and set at a length movable from a portion corresponding to the temporarily placing table 4 to respective portions corresponding to the two chuck tables. The monitor 10 is adapted to display the inspection results of a cut state of the wafer W and other various data thereof for an operator.

The chuck table 20 holds the wafer W. The cutting means 30 is provided with a cutting blade 33 which cuts the wafer W held on the chuck table 20. The processing-transfer means 40 processing-transfers the chuck table 20 in the X-axial direction. The indexing-transfer means 50 indexing-transfers the cutting means 30 in the Y-axial direction. The incision-transfer means 60 incision-transfers the cutting means 30 in the Z-axial direction. The alignment means 70 images the wafer W held by the chuck table 20 and detects an area to be cut. The alignment-indexing means 80 indexing-transfers the alignment means 70 in the Y-axial direction.

In the present embodiment, the chuck table 20 composes of a first chuck table 20a and a second chuck table 20b juxtaposed to each other in the Y-axial direction as shown in FIG. 2. According to this arrangement, as shown in FIGS. 2 to 4, also the cutting means 30, processing-transfer means 40, indexing-transfer means 50, incision-transfer means 60, alignment means 70 and alignment indexing-transfer means 80 includes of first and second cutting means 30a and 30b, first and second processing-transfer means 40a and 40b, first and second indexing-transfer means 50a and 50b, first and second incision-transfer means 60a and 60b, first and second alignment means 70a and 70b and first and second alignment-indexing-transfer means 80a and 80b, respectively. These members or means are arranged on a base 8 provided in the apparatus casing body 7. The configurations of the members or means are hereinafter described with reference to FIGS. 2 to 4.

The first and second chuck tables 20a, 20b are made of a porous material such as porous ceramic or the like and connected to suction means not shown. The first and second chuck tables 20a, 20b are allowed to selectively communicate with a suction source by the suction means to suck and hold the respective wafers W placed on the placing surfaces thereof. The first and second chuck tables 20a and 20b are turnably disposed on respective cylindrical members 21a and 21b and are connected to drive sources such as pulse motors not shown provided in the first and second cylindrical members 21a and 21b, respectively, so as to be turned appropriately.

Rectangular first and second cover members 22a and 22b are disposed on the upper ends of the cylindrical members 21a and 21b, respectively. First and second blade detection means 23a and 23b are disposed on the upper surfaces of the first and second cover members 22a and 22b in order to detect the positions of first and second cutting blades, respectively. Telescopic bellows not shown are connected to both the X-axial ends of the first and second cover members 22a, 22b. Thus, even if the first and second chuck tables 20a, 20b are processing-transferred to change their respective positions, the first and second cover members 22a and 22b along with the bellows constantly cover the first and second processing-transfer means 40a and 40b, respectively.

The first and second processing-transfer means 40a and 40b are adapted to processing-transfer (cutting-transfer) the first and second chuck tables 20a and 20b in the X-axial direction relative to the first and second cutting means 30a and 30b, respectively, by moving first and second support bases 41a and 41b mounted with the first and second cylindrical members 21a and 21b thereon, respectively, in the X-axial direction. The first and second processing-transfer means 40a, 40b include ball screws 42a and 42b disposed to extend in the X-axis direction; reversely rotatable pulse motors 43a and 43b connected to one ends of the ball screws 42a and 42b; and a pair of guide rails 44a and 44b disposed on the base in parallel to the ball screws 42a and 42b, respectively. The ball screws 42a and 42b are threadedly engaged with nuts not shown provided on the lower portions of the support bases 41a and 41b, respectively. The ball screws 42a and 42b are drivingly turned by the pulse motors 43a and 43b to reciprocate the support bases 41a and 41b in the X-axial direction along the guide rails 44a and 44b, respectively.

The cutting machine 1 of the present embodiment is provided with a support frame 9. The support frame 9 is disposed on the base 8 so as to straddle the guide rails 44a, 44b perpendicularly to the X-axial direction and to be formed like a gate in such a manner as not to impede the X-axial movement of the first and second chuck tables 20a, 20b. The first and second cutting means 30a, 30b, first and second indexing-transfer means 50a, 50b, first and second incision-transfer means 60a, 60b, first and second alignment means 70a, 70b and first and second alignment indexing-transfer members 80a, 80b are mounted on a support portion 9a extending along the Y-axial direction of the support frame 9. Incidentally, the support frame 9 is partially formed with supporting columns 9b, 9c on both sides thereof which are formed with respective increased width portions. The increased width portions are formed with respective openings 9d and 9e allowed to move the first and second cutting means 30a and 30b, respectively, therethrough in the Y-axial direction.

The first and second alignment means 70a and 70b are disposed on one surface, running in the X-axial direction, of the support portion 9a of the support frame 9 so as to correspond to the first and second chuck tables 20a and 20b, respectively. The first and second alignment means 70a and 70b include first and second movement blocks 71a and 71b, respectively, and first and second imaging means 72a and 72b attached to the first and second movement blocks 71a and 71b, respectively. Each of the first and second imaging means 72a and 72b is of an electronic microscope structure mounted with an imaging device such as a CCD, can image from above the wafer W held on each of the first and second chuck tables 20a, 20b, and outputs a picture signal resulting from the imaging to control means not shown. The first and second alignment means 70a, 70b are each shared by alignment, kerf check and inspection.

For alignment, the first and second alignment means 70a, 70b are used to provide positioning for cutting operation of the first and second cutting means 30a, 30b, by detecting an area to be cut on the basis of picture information of the wafer W obtained by the first and second imaging means 72a, 72b. For kerf check, the first and second alignment means 70a, 70b are used to position a cut groove (kerf) made in the wafer W at respective imaging positions of the first and second imaging means 72a, 72b, image the cut groove for creating picture information, and create cut groove date (a state of a width of the cut groove, a state of chip, etc.) through picture processing. For inspection, the wafer W that has been cut is positioned right below the first and second alignment means 70a, 70b, and imaged by the first and second imaging means 72, 72b to create picture information, which is used to inspect whether or not to accept the cut state of a cut groove.

The first and second alignment indexing-transfer means 80a and 80b are adapted to indexing-transfer, in the Y-axial direction, the first and second alignment means 70a and 70b to the wafers W on the first and second chuck tables 20a and 20b by moving the first and second movement blocks 71a and 71b mounted with the first and second movement blocks 71a and 71b thereon, respectively. The first and second alignment indexing-transfer means 80a and 80b include ball screws 81a and 81b mounted on the one surface of the support portion 9a to extend in the Y-axial direction; and pulse motors 82a and 82b connected one ends of the ball screws 81a and 81b, respectively. In addition, the first and second alignment indexing transfer means 80a and 80b include a pair of common guide rails 83 disposed on the one surface of the support portion 9a in parallel to the ball screws 81a, 81b. The ball screws 81a and 81b are threadedly engaged with respective nuts not shown provided in the movement blocks 71a and 71b, respectively. The ball screws 81a and 81b are drivingly turned by reversely rotatable pulse motors 82a and 82b, respectively, whereby the movement blocks 71a and 71b are reciprocated in the Y-axial direction while being guided by the guide rails 83.

The first and second cutting means 30a, 30b are disposed below the support portion 9a of the support frame 9. As shown in FIGS. 3 and 4, the first and second cutting means 30a and 30b respectively include spindle housings 31a and 31b; rotational spindles 32a and 32b rotatably supported by the spindle housing 31a and 31b; first and second cutting blades 33a and 33b replaceably attached to the one ends of the rotational spindles 32a and 32b; first and second cutting water supply nozzles 34a and 34b adapted to supply cutting water to the first and second cutting blades 33a and 33b; blade covers 35a and 35b covering the first and second cutting blades 33a and 33b; servo motors not shown for drivingly rotating the rotational spindles 32a and 32b. The rotational spindles 32a, 32b are disposed to have respective axial directions which are aligned with each other in an indexing direction indicated with the Y-axial direction. In addition, the first and second cutting blades 33a, 33b that have the same structure for dual cutting are disposed oppositely to each other in the Y-axial direction so as to cut one and the same wafer W in parallel and at the same time.

The first and second incision-transfer means 60a and 60b incision-transfer, in the Z-axial direction, the first and second cutting blades 33a and 33b to the wafer W on the chuck table 20a or 20b by moving in the Z-axial direction the first and second incision-movement bases 61a and 61b mounted respectively with the first and second cutting means 30a and 30b. The first and second incision-movement bases 61a and 61b are each formed in an almost L-shape as viewed in the Y-axial direction and are disposed on the other surface of the support portion 9a in the X-axial direction. In addition, the spindle housing 31a and 31b are attached directly below the first and second cutting blades 33a and 33b, respectively, and the first and second cutting blades 33a and 33b are disposed inside the spindle housings 31a and 31b, respectively.

The first and second incision-transfer means 60a and 60b respectively include boll screws 62a and 62b each disposed to extend in the Z-axial direction; pulse motors 63a and 63b connected respectively to one ends of the ball screws 62a and 62b; and a pair of guide rails 64a and 64b disposed on the first and second indexing movement bases 51a and 51b so as to be parallel to the ball screws 62a and 62b. Respective nuts not shown provided in the incision movement bases 61a and 61b are threadedly engaged with the ball screws 62a and 62b, respectively. The ball screws 62a and 62b are drivingly rotated by reversely rotatable pulse motors 63a and 63b, whereby the incision-movement bases 61a and 61b are reciprocated in the Z-axial direction while being guided by the guide rails 64a and 64b, respectively.

The first and second indexing-transfer means 50a and 50b are adapted to indexing-transfer, in the Y-axial direction, the first and second cutting blades 33a and 33b, respectively, to the wafer W on the chuck table 20a or 20b by moving, in the Y-axial direction, the first and second indexing-transfer bases 51a and 51b provided respectively with the first and second incision-movement bases 61a and 61b movable in the Z-axial direction. The first and second indexing transfer means 50a and 50b respectively include ball screws 52a and 52b; pulse motors 53a and 53b connected respectively to one ends of the ball screws 52a and 52b; a pair of common guide rails 54 on the other surface of the support portion 9a in the X-axial direction so as to be parallel to the ball screws 52a and 52b. Respective nuts not shown provided in the indexing movement bases 51a and 51b are threadedly engaged with the ball screws 52a and 52b. The ball screws 52a and 52b are driven for rotation by reversely rotatable pulse motors 53a and 53b, respectively, whereby the indexing-movement bases 51a and 51b are reciprocated in the Y-axial direction while being guided by the guide rails 54. Amounts in which the first and second cutting blades 33a and 33b are indexing-transferred by the first and second indexing transfer means 50a and 50b, respectively, are set so that the first and second cutting blades 33a, 33b can be moved between the chuck tables 20a, 20b.

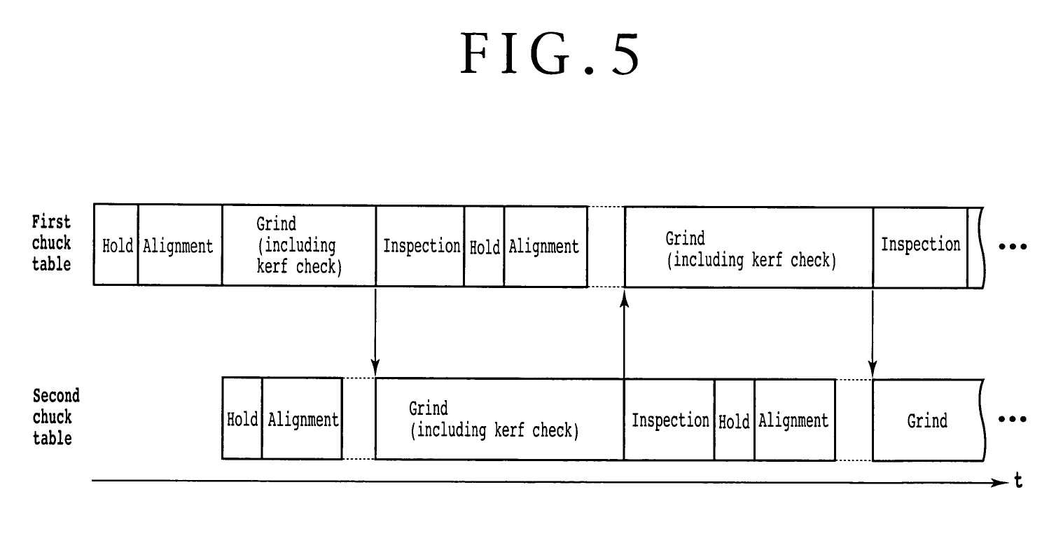

A description is next made of a method of processing a wafer W using such a cutting machine 1 with reference to FIG. 5. FIG. 5 is a time-series explanatory diagram illustrating processes performed correspondingly to first and second chuck tables 20a, 20b. A wafer W is first taken out onto the temporarily placing table 4 by the taking-out means 3. The wafer W taken out onto the temporarily placing table 4 is conveyed onto the first chuck table 20a by the conveying means 5. At this time, the first chuck table 20a is positioned at a wafer attachment-detachment position shown in FIG. 2. Suction means not shown is actuated to suck and hold the wafer W onto the first chuck table 20a (wafer-holding step).

Subsequently, the first chuck table 20a that sucks and holds the wafer W is moved to an alignment area of the first alignment means 70a by operating the first processing transfer means 40a. The first alignment indexing-transfer means 80a is operated to move the first alignment means 70a so that the wafer W held by the first chuck table 20a is positioned immediately below the first imaging means 72a of the first alignment means 70a. The first imaging means 72a images the front surface of the wafer W on the first chuck table 20a and detects the predetermined dividing lines formed on the front surface of the wafer W, which are provided for positioning of the first and second cutting blades 33a, 33b for their cutting operation (alignment step).

While the first alignment means 70a performs the alignment step on the wafer W held on the first chuck table 20a as described above, a wafer W is conveyed by the conveying means 5 onto the second chuck table 20b positioned at a wafer attachment-detachment position shown in FIG. 2. Suction means not shown is operated to suck and hold the wafer W placed on the second chuck table 20b thereon (wafer holding step).

Subsequently, the second chuck table 20b that sucks and holds the wafer W is moved to an alignment area of the second alignment means 70b by operating the second processing transfer means 40b. The second alignment indexing-transfer means 80b is operated to move the second alignment means 70b so that the wafer W held by the second chuck table 20b is positioned immediately below the second imaging means 72b of the second alignment means 70b. The second imaging means 72b images the front surface of the wafer W on the second chuck table 20b and detects the predetermined dividing lines formed on the front surface of the wafer W, thus, performing an alignment step. This alignment step is performed similarly to the alignment step described earlier.

On the other hand, after the alignment step by the first imaging means 72a is finished as described above, the indexing-transfer means 50a of the first cutting means 30a is operated to position the first cutting blade 33a of the first cutting means 30a at a position corresponding to a central one of the predetermined dividing lines formed in the wafer W held on the first chuck table 20a. Further, the first incision-transfer means 60a is operated to lower and position the first cutting blade 33a at a predetermined incision-transfer position. Similarly, the indexing-transfer means 50b of the second cutting means 30b is operated to position the second cutting blade 33b of the second cutting means 30b at a position corresponding to an endmost one of the predetermined dividing lines formed in the wafer W held on the first chuck table 20a. Further, the second incision-transfer means 60b is operated to lower and position the second cutting blade 33b at a predetermined incision-transfer position.

The first processing transfer means 40a is operated to processing-transfer the first chuck table 20a in the X-axial direction while rotating the respective first and second cutting blades 33a and 33b of the first and second cutting means 30a and 30b. Thus, the wafer W held on the first chuck table 20a is cut along the prescribed ones of the predetermined dividing lines by the high-speed rotating first and second cutting blades 33a, 33b (cutting step). In other words, as shown in FIG. 5, the first and second cutting blades 33a, 33b concurrently cut one and the same wafer W in parallel by a dual-cutting method.

The wafer W held on the first chuck table 20a is cut along the prescribed ones of the predetermined dividing lines. Thereafter, the respective first and second indexing-transfer means 50a, 50b of the first and second cutting means 30a, 30b are indexing-transferred in the Y-axial direction by the spacing between adjacent predetermined dividing lines and the cutting step described above is performed again. In this way, the cutting step is performed each time while repeating the indexing-transfer, whereby the wafer W is cut along all the predetermined dividing lines formed in a prescribed direction. After the wafer W is cut along all the predetermined dividing lines formed in the prescribed direction, the first chuck table 20a holding the wafer W is turned at an angle of 90 degrees. Then, the cutting step involving the indexing-transfer described above is performed on the wafer W held by the first chuck table 20a. In this way, the wafer W is cut along all the predetermined dividing lines formed in a lattice-like manner and divided into individual device chips. Incidentally, although the wafer W is divided into the individual device chips, since wafer W is stuck to the holding tape T attached to the annular frame F, the form of the wafer is maintained without being parted.

During such a cutting step, a kerf check is performed to monitor the cut state of the wafer W at predetermined timing by using the first imaging means 72a of the first alignment means 70a corresponding to the first chuck table 20a holding the cutting wafer W under cut. More specifically, the respective cut grooves (kerfs) cut by the first and second cutting blades 33a and 33b are imaged by the first imaging means 72a, picture information thus imaged is picture-processed to determine the measurements of a kerf position. If the kerf position deviates from a preset reference position (hairline), the kerf position is automatically corrected (hairline matching). Also during the kerf check, the width of a kerf and the size of chipping are measured. Data such as an amount of kerf position deviating from a reference value (an off-center amount), the width of a kerf and the size of chipping, etc. are displayed on the screen of the monitor 10 as may be necessary.

After the cutting step for the wafer W held on the first chuck table 20a is finished as described above, a cutting step by the first and second cutting blades 33a, 33b is performed on a wafer W that is held on the second chuck table 20b, has already been subjected to the alignment step and is not yet cut, in the dual-cutting method similarly to the above-described case. During this cutting step, similarly to the above-described kerf check, a kerf check is performed to monitor the cut state of the wafer W at predetermined timing by using the second imaging means 72b of the second alignment means 70b corresponding to the second chuck table 20b holding the cutting wafer W under cut.

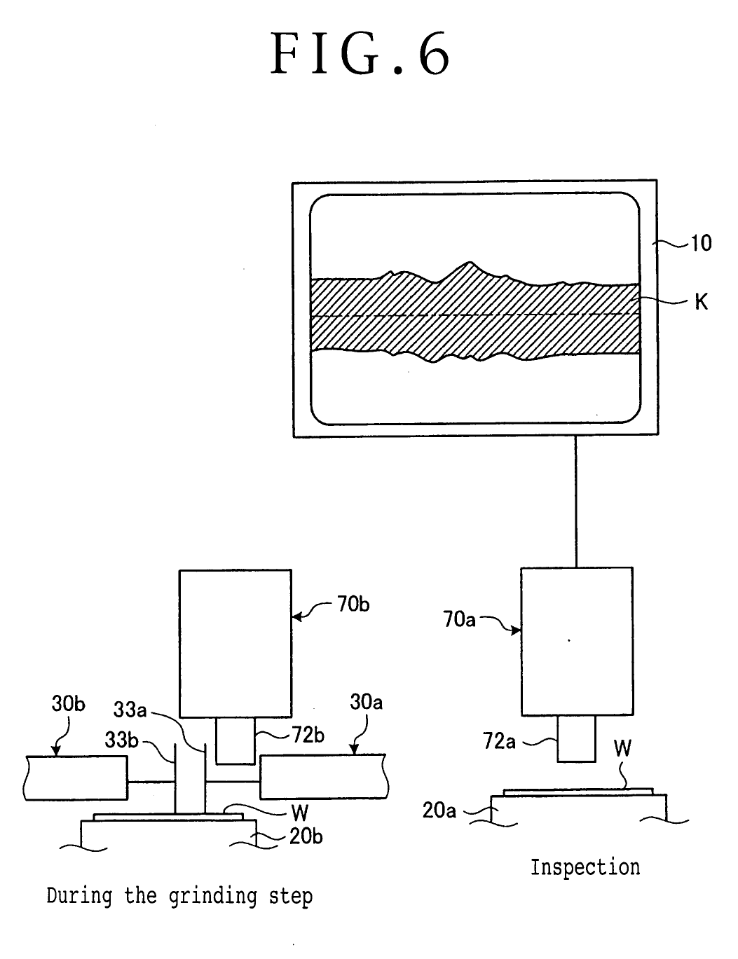

On the other hand, after the cutting step for the wafer W held on the first chuck table 20a is finished, during the cutting step for the wafer W held on the second chuck table 20b, the wafer W that has been cut and is held by the first chuck table 20 is positioned immediately below the first imaging means 72a of the first alignment means 70a for inspecting the cut state thereof as shown in FIG. 6 (inspection step). Specifically, similarly to the kerf check during the cutting, the grooves cut by the first and second cutting blades 33a, 33b are imaged by the first imaging means 72a, picture information thus imaged is picture-processed, and the cut state such as the state of the width of the cut grooves, the state of chipping and the like is inspected. For example, the cut state of a cut groove K is displayed as necessary on the screen of the monitor 10 as exemplified in FIG. 6.

After the inspection step is finished, the first chuck table 20a holding the wafer W that has been inspected is moved from the cutting area toward the wafer attachment-detachment position by the first processing transfer means 40a. Suction-holding the wafer W is released at the wafer attachment-detachment position. The wafer W that has been inspected and divided into individual device chips are conveyed to a subsequent step by the conveying means 5. After the conveyance of the wafer W that has been divided to the subsequent step is finished, a wafer-holding step for conveying and holding a subsequent wafer W onto the first chuck table 20 and an alignment step for the wafer W thus held are sequentially performed during the cutting step for the wafer W held by the second chuck table 20b. The inspection step, wafer-holding step and alignment step are completed in a shorter time than the cutting step. Therefore, it is sufficiently possible to perform the inspection step, wafer-holding step and alignment step for the one chuck table 20a during the cutting step for the other chuck table 20b.

Subsequently, after the cutting step for the wafer W held on the second chuck table 20b is finished, the cutting step by the first and second cutting blades 33a, 33b is performed on the wafer W that is held on the first chuck table 20a, has been subjected to the alignment step and is not yet cut in the dual-cutting method similarly to the case described above. During such a cutting step, a kerf check is performed similarly to the case of the kerf check described above to monitor the cut state of the wafer W at predetermined timing by using the first imaging means 72a of the first alignment means 70a corresponding to the first chuck table 20a holding the cutting wafer W under cut.

After the cutting step for the wafer W held on the second chuck table 20b is finished, during the cutting step for the wafer W held on the first chuck table 20a, the wafer W that has been cut and is held by the second chuck table 20b is positioned immediately below the second imaging means 72b of the second alignment means 70b for checking the cut state thereof (inspection step). Specifically, similarly to the kerf check during the cutting, the grooves cut by the first and second cutting blades 33a, 33b are imaged by the second imaging means 72b, picture information thus imaged is picture-processed, and the cut state such as the state of the width of the cut grooves, the state of a chip and the like is inspected. For example, the cut state of a cut groove is displayed as necessary on the screen of the monitor 10.

After the check step is finished, the second chuck table 20b holding the wafer W that has been inspected is moved from the cutting area toward the wafer attachment-detachment position by the second processing transfer means 40b. Suction-holding the wafer W is released at the wafer attachment-detachment position. The wafer W that has been inspected and divided into individual device chips are conveyed to a subsequent step by the conveying means 5. After the conveyance of the wafer W that has been divided to the subsequent step is finished, a wafer-holding step for conveying and holding a subsequent wafer W onto the second chuck table 20b and an alignment step for the wafer W thus held are sequentially performed during the cutting step for the wafer W held by the first chuck table 20a.

In such a similar way, the wafer-holding step, alignment step, cutting step and inspection step are subsequently repeated by concurrently using the first and second chuck tables 20a, 20b. Incidentally, of the two cutting steps that are alternately performed by using the first and second chuck tables 20a, 20b, a precedent cutting step means a first cutting step of the present invention and a subsequent cutting step means a second cutting step of the present invention.

According to the wafer cutting method of the present embodiment, that the chuck tables 20a, 20b are two in number is used to perform the inspection step for inspecting the cut state of the wafer W that has been cut such as the state of the width of a cut groove, the state of a chip, and the like during cutting of the wafer W held by the other chuck table 20a or 20b. Thus, the cut state of the wafer W can be inspected without sacrificing throughput, thereby improving the productivity of wafers W to be cut.

According to the wafer cutting method of the present embodiment, not only the inspection step but also the subsequent wafer holding step and alignment step after the completion of the inspection step are performed during cutting of the wafer W held by the other chuck table 20a or 20b. Thus, it is possible to improve the productivity of the wafers W by optimizing the fact that the chuck tables 20a, 20b are two in number.

According to the wafer processing method of the present embodiment, also the two alignment means 70a and 70b are used so as to correspond to the two chuck tables 20a and 20b, respectively, and the corresponding alignment means 70a or 70b is used to perform a kerf check for monitoring the cut state of the wafer W during the cutting step of the wafer W. Thus, the kerf check for the wafer W under cut is appropriately performed and automated correction such as hairline matching or the like can be performed without being subjected to the restraint of the inspection step or alignment step in the other chuck table 20a or 20b. Thus, cutting performance is improved to increase the productivity of the wafers.

The present embodiment describes the cutting means 30 of the dual-cutting method by way of example in which the first and second cutting blades 33a, 33b having the same structure are provided oppositely to each other and simultaneously cuts one and the same wafer W in parallel. However, the present invention can be applied to a step-cutting method. In this method, a first and second cutting means having respective first and second cutting blades different from each other in cutting depth for a wafer W are provided and the first and second cutting blades cut one and the same predetermined dividing line in two stages. Further, the present invention can be applied to a case where cutting means having only one cutting blade is used to cut a wafer W. In the present embodiment, the cutting step and other steps are first performed by the first chuck table 20a and other associated components; however, they may first be performed by the second chuck tale 20b and other associated components.

The present invention is not limited to the details of the above described preferred embodiments. The scope of the invention is defined by the appended claims and all changes and modifications as fall within the equivalence of the scope of the claims are therefore to be embraced by the invention.

What is claimed is:

1. A wafer processing method using a cutting machine that includes:
a chuck table for holding a wafer;
cutting means attached with a cutting blade for cutting the wafer held by the chuck table;
processing-transfer means for processing-transferring the chuck table in an X-axial direction;
indexing-transfer means for indexing-transferring the cutting means in a Y-axial direction perpendicular to the X-axial direction;
a cassette table with a cassette storing a plurality of wafers mounted thereon;
taking-out means for taking out a wafer from the cassette;
a temporarily placing table adapted to temporarily place the wafer thus taken out;
conveying means for conveying to the chuck table the wafer thus temporarily placed on the temporarily placing table;
alignment means for imaging the wafer held by the chuck table and detecting an area to be cut;
wherein the chuck table includes first and second chuck tables juxtaposed to each other and the processing-transfer means includes first processing-transfer means for processing-transferring the first chuck table and second processing-transferring means for processing-transferring the second chuck table, the method comprising:
a wafer holding step in which each of the first and second chuck tables holds a wafer that is taken out from the cassette to the temporarily placing table and then conveyed by the conveying means;
an alignment step in which the wafer held by each of the first and second chuck tables is positioned immediately below the alignment means, which detects an area to be cut;
a first cutting step in which the cutting blade of the cutting means is positioned for the wafer that has been held by the first chuck table and has been subjected to the alignment step;
a second cutting step in which after the first cutting step has been finished, the cutting blade of the cutting means is positioned for and cuts the wafer that has been held by the second chuck table, subjected to the alignment step and is not yet cut;
an inspection step in which after the first cutting step has been finished, during the second cutting step, the wafer that has been cut in the first cutting step and held by the first chuck table is positioned immediately below the alignment means, which inspects a cut state.

2. The wafer processing method according to claim 1, wherein the subsequent wafer holding step and alignment step for the first chuck table in which the inspection step has been finished are performed during the second cutting step.
